(19) United States
(12) Patent Application Publication
(10) Pub. No.: US 2016/0202330 A1
(43) Pub. Date: Jul. 14, 2016

(54) MAGNETIC SENSOR ELEMENT

(71) Applicant: HITACHI, LTD., Chiyoda-ku, Tokyo (JP)

(72) Inventors: Hiroyuki YAMAMOTO, Tokyo (JP); Akihiko KANDORI, Tokyo (JP); Katsuya MIURA, Tokyo (JP)

(73) Assignee: Hitachi, Ltd., Chiyoda-ku, Tokyo (JP)

(21) Appl. No.: 14/911,695

(22) PCT Filed: Sep. 9, 2013
(86) PCT No.: PCT/JP2013/074223

§ 371 Date: Feb. 11, 2016

(51) Int. Cl. G01R 33/09; H01L 43/08

(52) U.S. Cl. CPC G01R 33/098; G01R 33/093; H01L 43/08

(57) ABSTRACT

Provided is a magnetic sensor device having a structure in which a plurality of MTJ structures, each using a ferromagnetic layer having an in-plane axis of easy magnetization and a ferromagnetic layer having a perpendicular axis of easy magnetization, are laminated. By a single device, magnetic fields in two or more directions can be sensed, or a plurality of magnetic field ranges including a small magnetic field and a relatively large magnetic field can be sensed.

### TECHNICAL FIELD

The present invention relates to a magnetic sensor device using a magnetoresistive effect device.

### BACKGROUND ART

In recent years, a magnetic sensor is used in various applications such as an in-vehicle axle rotation sensor, an in-vehicle cam/crank angle position sensor, a current sensor for an electric car, and an electronic compass for a portable terminal. A Magnetic Tunneling Junction (MTJ) device using a Tunneling Magnetoresistive (TMR) effect is promising as a small-sized and low-power-consumption magnetic sensor. The MTJ device has a basic configuration in which an insulating barrier layer is interposed between two ferromagnetic layers (a pinned layer and a free layer). A magnetization direction of the pinned layer is fixed in one direction while a magnetization direction of the free layer is rotated by an external magnetic field. Since resistance of the device changes depending on the angular difference between their magnetization directions, a change in the external magnetic field can be detected as a resistance change of the device.

For example, in an application of measuring an orientation as in the electronic compass, magnetic fields in a plurality of directions (an X direction, a Y direction, and a Z direction) need to be sensed. Since the conventional MTJ device serving as the magnetic sensor has only one direction for sensing the magnetic field, a plurality of devices need to be mounted to do such measurement (e.g., PTL 1).

### CITATION LIST

### Patent Literature

PTL 1: JP 2004-6752 A

### SUMMARY OF INVENTION

### Technical Problem

As described above, the conventional MTJ device still has problems in easiness of mounting and size reduction. Also, in an application of reading a current value from a magnetic field generated by current, such as the current sensor for the electric car, there is a need for measurement of the current values in various ranges. In this case, a plurality of sensors each having appropriate magnetic field sensitivity need to be used selectively depending on the intensity of the current to be measured, which is problematic in terms of space saving and cost reduction.

In consideration of the above problems, the present invention provides an MTJ device excellent in size reduction and high sensitivity enabling magnetic fields in a plurality of directions to be measured by a single device with high sensitivity or a sensor device enabling magnetic fields in a narrow range and in a wide range to be measured by a single device with high sensitivity.

### Solution to Problem

The present invention proposes a magnetic sensor device including a plurality of MTJ structures in each of which a ferromagnetic layer having perpendicular magnetic anisotropy and a ferromagnetic layer having in-plane magnetic anisotropy are combined. In a preferred configuration, CoFeB that can control perpendicular/in-plane magnetic anisotropy in accordance with a film thickness is used as the ferromagnetic layer.

A magnetic sensor device according to the present invention is a magnetic sensor device in which at least two tunneling magnetoresistive effect devices are laminated, each of which includes a free layer whose magnetization direction changes depending on an external magnetic field, a pinned layer whose magnetization direction is fixed in one direction, and an oxide tunneling barrier layer arranged between the free layer and the pinned layer. An upper electrode layer and a lower electrode layer are provided at an upper portion and a lower portion of each tunneling magnetoresistive effect device. To the upper electrode layer and the lower electrode layer are connected electrode terminals to measure resistance of the tunneling magnetoresistive effect device. In at least either one of the tunneling magnetoresistive effect devices, axes of easy magnetization of the free layer and the pinned layer are perpendicular in an in-plane direction and in a perpendicular direction.

In one aspect, in either one of the two tunneling magnetoresistive effect devices, an axis of easy magnetization of the pinned layer is in a perpendicular direction. Also, in another aspect, in either one of the two tunneling magnetoresistive effect devices, an axis of easy magnetization of the free layer is in a perpendicular direction.

### Advantageous Effects of Invention

By using a magnetic sensor device according to the present invention, since magnetic fields in two or more directions can be sensed by a single device, a smaller-sized magnetic sensor reducing a mounting space can be achieved. Also, by using a device of type having sensitivity to a weak magnetic field region and a strong magnetic field region, space saving and cost reduction can be achieved.

Problems, configurations, and effects other than the aforementioned ones become apparent in the following description of embodiments.

### BRIEF DESCRIPTION OF DRAWINGS

FIG. 1 is a schematic cross-sectional view of a magnetic sensor device according to Embodiment 1.

FIG. 2 is a schematic view illustrating relationship between an external magnetic field and a resistance change in an MTJ structure.

FIG. 3 is a schematic view illustrating relationship between an external magnetic field and a resistance change in an MTJ structure.

FIG. 4 is a schematic cross-sectional view illustrating a more specific form of the magnetic sensor device according to Embodiment 1.

FIG. 5 is a schematic view illustrating a more practical mounting form of the magnetic sensor device according to Embodiment 1.

FIG. 6 is a schematic view illustrating a mounting form of the magnetic sensor device according to Embodiment 1.

FIG. 7 illustrates arrangement of the magnetic sensor devices for achieving a magnetic sensor in three axial directions.

FIG. 8 is a schematic cross-sectional view of a magnetic sensor device according to Embodiment 2.

FIG. 9 is a schematic view illustrating external magnetic field dependence of resistance of the magnetic sensor device according to Embodiment 2.

FIG. 10 is a schematic cross-sectional view of a magnetic sensor device according to Embodiment 3.

FIG. 11 is a schematic cross-sectional view of a magnetic sensor device according to Embodiment 4.

FIG. 12 is a schematic cross-sectional view of a magnetic sensor device according to Embodiment 5.

### DESCRIPTION OF EMBODIMENTS

Hereinbelow, embodiments of the present invention will be described with reference to the drawings.

### <Embodiment 1>

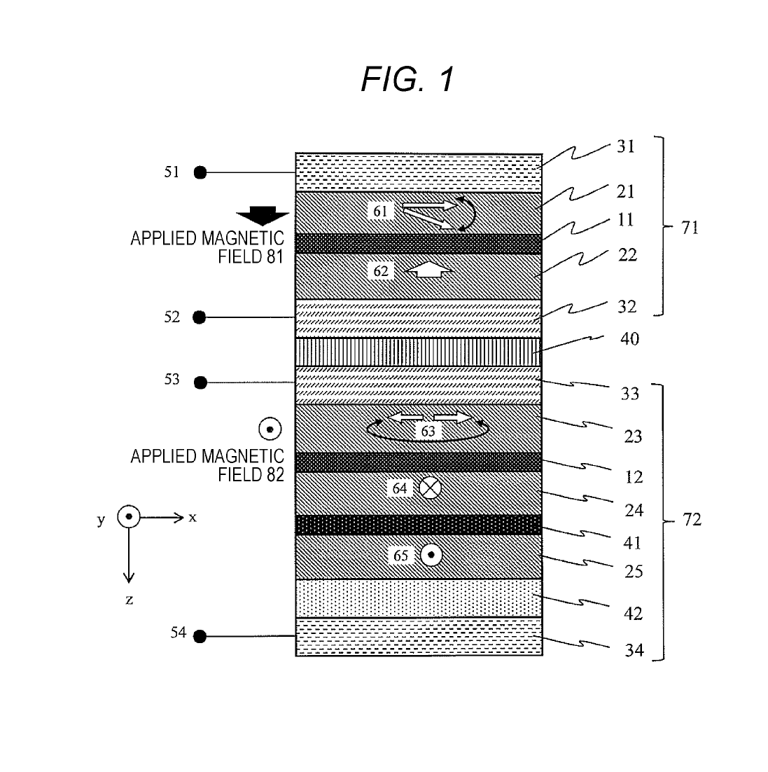

Embodiment 1 proposes a magnetic sensor that can measure magnetic fields in two directions. FIG. 1 is a schematic cross-sectional view of a sensor device according to Embodiment 1. The sensor device is configured by laminating a plurality of metal thin films and insulating thin films on a wafer substrate as in FIG. 1. In this device, an upper-stage MTJ structure 71 and a lower-stage MTJ structure 72 are laminated, and an insulating spacer layer 40 is arranged between the structures.

First, the lower-stage MTJ structure 72 will be described. The MTJ structure 72 is a magnetic sensor structure using general in-plane magnetic anisotropic ferromagnetic layers used conventionally. A lower electrode 34 is constituted by a laminated film in which Ta (film thickness: 5 nm), Ru (film thickness: 10 nm), Ta (film thickness: 5 nm), and NiFe (film thickness: 3 nm) are laminated in this order from the bottom. On the lower electrode 34, MnIr (8 nm) is laminated as an antiferromagnetic layer 42. In addition, a pinned layer second ferromagnetic layer 25, a non-magnetic layer 41, and a pinned layer first ferromagnetic layer 24 are laminated in this order. The pinned layer second ferromagnetic layer 25 is Co₅₀Fe₅₀ (2.5 nm), the non-magnetic layer 41 is Ru (0.8 nm), and the pinned layer first ferromagnetic layer 24 is Co₂₀Fe₆₀B₂₀ (3 nm). Respective magnetizations 64 and 65 of the pinned layer first ferromagnetic layer 24 and the pinned layer second ferromagnetic layer 25 are stabilized to be antiparallel with each other due to antiferromagnetic coupling of the pinned layer first ferromagnetic layer 24 and the pinned layer second ferromagnetic layer 25 via the Ru of the non-magnetic layer 41. This is a pinned layer of a so-called synthetic ferromagnetic structure and is effective to fix a magnetization of the pinned layer strongly. On the pinned layer, MgO (1.5 nm) is laminated as a barrier layer 12, on which Co₂₀Fe₆₀B₂₀ (2 nm) as a free layer 23 and a laminated film of Ta (5 nm) and Ru (5 nm) as an upper electrode 33 are formed. To the upper electrode 33 and the lower electrode 34, electrode terminals 53 and 54 are respectively connected to measure resistance.

Next, a response of the device to the magnetic field will be described. The magnetization 65 of the pinned layer is strongly fixed in a +y direction in the figure by exchange bias of the antiferromagnetic layer 42. As described above, due to the antiferromagnetic coupling via the Ru, the magnetization 64 of the pinned layer is stabilized to be antiparallel to the magnetization 65 and is thus fixed in a −y direction. Conversely, a magnetization 63 of the free layer has an axis of easy magnetization in an x direction. That is, in a situation of no external magnetic field, the axis of easy magnetization of the magnetization 63 of the free layer and an axis of easy magnetization of the magnetization 64 of the pinned layer opposed via the barrier layer 12 are perpendicular in a plane. This is an initial state.

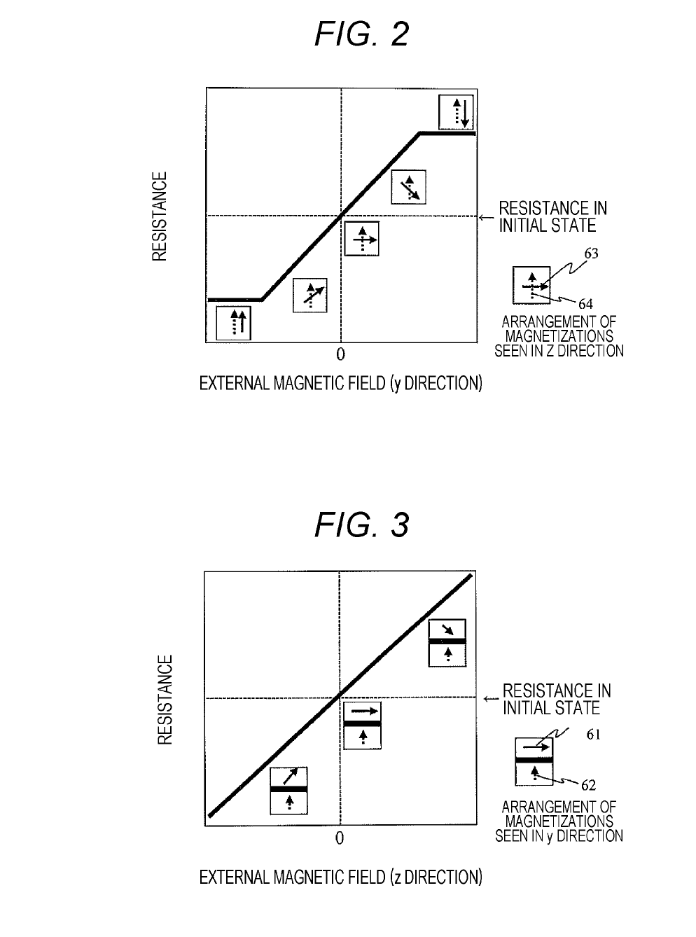

Subsequently, as illustrated in the figure, when a magnetic field 82 in the +y direction is applied, for example, the magnetization 63 of the free layer is rotated in the plane to face in the +y direction. At this time, since arrangement of the magnetizations 63 and 64 is closer to antiparallel arrangement, the resistance of the MTJ structure 72 (the resistance between the electrode terminals 53 and 54) increases further than that in the initial state. Conversely, when the external magnetic field is applied in the −y direction, the magnetization 63 of the free layer is rotated to face in the −y direction. Since arrangement of the magnetizations 63 and 64 is closer to parallel arrangement, the resistance of the MTJ structure 72 decreases further than that in the initial state. FIG. 2 is a schematic view illustrating the relationship between the external magnetic field and the resistance change in this MTJ structure. With use of a region in which the resistance linearly changes in accordance with the external magnetic field as illustrated in the figure, the magnetic field can be sensed.

Next, the upper-stage MTJ structure 71 will be described. A lower electrode 32 is constituted by a laminated film in which Ta (film thickness: 5 nm), Ru (film thickness: 10 nm), and Ta (film thickness: 5 nm) are laminated in this order from the bottom. On the lower electrode 32, a pinned layer 22, a barrier layer 11, and a free layer 21 are laminated in this order. Co₂₀Fe₆₀B₂₀ (1 nm) is used as the pinned layer 22, MgO (1.5 nm) is used as the barrier layer 11, and Co₂₀Fe₆₀B₂₀ (2 nm) is used as the free layer 21. On the free layer 21, a laminated film of Ta (5 nm) and Ru (5 nm) is formed as an upper electrode 31. To the upper electrode 31 and the lower electrode 32, electrode terminals 51 and 52 are respectively connected to measure resistance. In this MTJ structure 71, a magnetization 62 of the pinned layer 22 faces in a direction perpendicular to a film plane. The reason for this is that setting a film thickness of the Co₂₀Fe₆₀B₂₀ as short as approximately 1 nm increases an influence of interface magnetic anisotropy with the MgO interface and causes an axis of easy magnetization of the pinned layer 22 to change from a direction in the film plane to the film plane perpendicular direction. On the other hand, a magnetization 61 of the free layer 21 faces in the x direction in the film plane. The reason for this is that the free layer 21 is the 2-nm Co₂₀Fe₆₀B₂₀, which is relatively thick, and that an axis of easy magnetization of the free layer 21 faces in the in-plane direction. Since the perpendicular magnetic anisotropy of the pinned layer 22 is generally stronger than the in-plane magnetic anisotropy, the magnetization 62 can be fixed in a stable manner with no antiferromagnetic layer. In a case in which the magnetization of the pinned layer 22 is desired to be fixed more strongly, an antiferromagnetic layer may be inserted between the lower electrode 32 and the pinned layer 22 as needed.

Next, a response of this MTJ structure 71 to the magnetic field will be described. First, in an initial state with no external magnetic field, the magnetization 61 of the free layer faces in the in-film-plane direction while the magnetization 62 of the pinned layer faces in the film plane perpendicular direction, and the magnetizations 61 and 62 are perpendicular to each other. As illustrated in the figure, when an external magnetic field 81 in a +z direction is applied, the magnetization 61 of the free layer is rotated to face in the +z direction. Since arrangement of the magnetization 61 with the magnetization 62 is closer to antiparallel arrangement, the resistance increases. Conversely, when the external magnetic field is applied in a −z direction, the magnetization 61 of the free layer faces in the −z direction, arrangement of the magnetization 61 with the magnetization 62 is closer to parallel arrangement, and the resistance decreases. FIG. 3 is a schematic view illustrating the relationship between the external magnetic field and the resistance change in this MTJ structure. With use of a region in which the resistance linearly changes in accordance with the external magnetic field as illustrated in the figure, the magnetic field can be sensed.

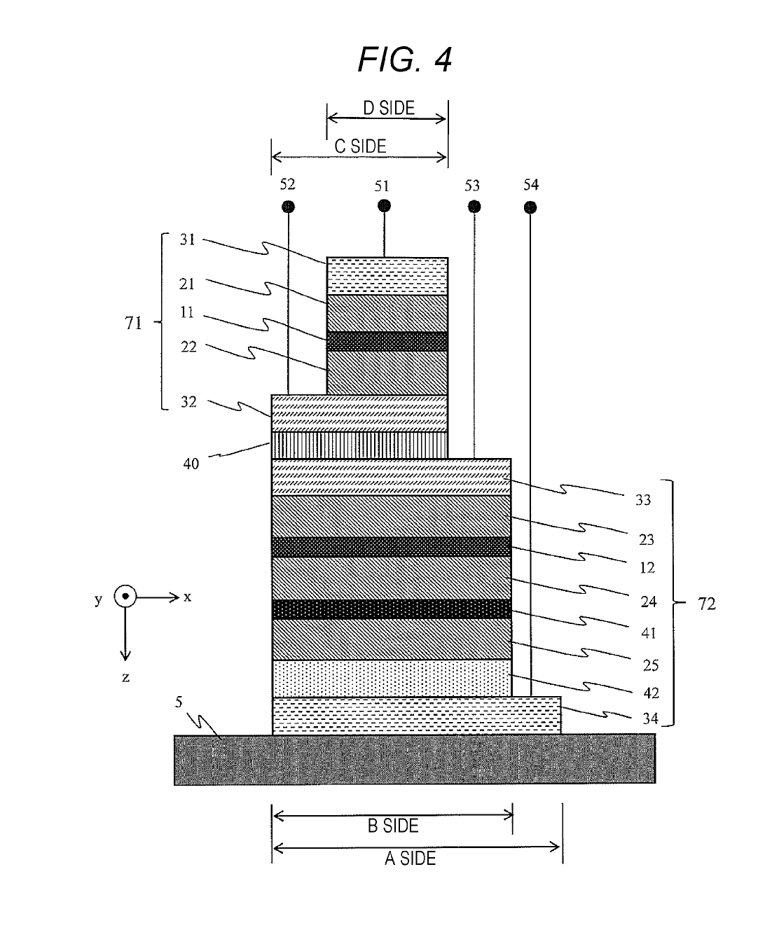

The structure and the operation of the device have been described above with reference to FIGS. 1, 2, and 3. Next, a more specific device structure and a method for manufacturing the device for mounting will be described. FIG. 4 is a schematic cross-sectional view of the device structure. The device is processed in a step-like pillar shape so that the electrodes can be connected from an upper portion to the predetermined layers of the laminated thin film constituting the device. As the manufacturing method, the laminated thin film is first formed on an Si substrate 5 having a thermally-oxidized film by means of an RF sputtering method using Ar gas. The materials and film thicknesses of the respective thin films are those described above. After the laminated thin film is formed, the entire laminated thin film is processed in a pillar shape of 45×30 μm as seen from an upper portion (side A having 45 μm in the figure) by means of photolithography and ion beam etching. Subsequently, the laminated thin film is processed in a pillar shape having a size of 40×30 μm (side B having 40 μm in the figure), which is smaller than the above pillar. At this time, etching stops at an upper portion of the lower electrode 34. Similarly, the laminated thin film is then processed in a pillar shape having a size of 35×30 μm (side C having 35 μm in the figure), which is smaller than the above pillar. At this time, etching stops at an upper portion of the upper electrode 33. Similarly, the laminated thin film is then processed in a pillar shape having a size of 30×30 μm (side D having 30 μm in the figure), which is smaller than the above pillar. At this time, etching stops at an upper portion of the lower electrode 32. After the step-like pillar is formed as above, the entirety is covered with an interlayer insulating film (Al₂O₃), and contact halls to be connected to the electrode terminals 51, 52, 53, and 54 are formed by means of the photolithography and the ion beam etching. Thereafter, an electrode thin film of Cr (film thickness: 5 nm) and Au (film thickness: 100 nm) is formed and is lastly patterned to produce the electrode terminals 51, 52, 53, and 54.

After the manufacture of the device in the above process, a heat treatment is performed twice to magnetize the pinned layers and increase a resistance change ratio (a TMR ratio). In the first heat treatment, a 300° C. treatment is performed in a state in which a magnetic field is applied in the x direction. As a result, the axes of easy magnetization of the free layer 21 and the free layer 23 face in the x direction. At the same time, the amorphous Co₂₀Fe₆₀B₂₀ (the free layer 21, the pinned layer 22, the free layer 23, and the pinned layer 24) is oriented in bcc (001) with the barrier layers 11 and 12 of MgO used as templates, and a high TMR ratio is achieved. In the second heat treatment, a 200° C. treatment is performed in a state in which a magnetic field is applied in the y direction. As a result, the magnetizations of the pinned layers 24 and 25 in the MTJ structure 72 are fixed in the y direction as in FIG. 1. Since a heat treatment temperature at this time is lower than the first one, the axes of easy magnetization of the free layers 21 and 23 fixed in the x direction in the first treatment do not change. Also, since the axis of easy magnetization of the pinned layer 22 having the perpendicular magnetic anisotropy is the film plane perpendicular direction in a stable manner regardless of the magnetic field applying direction during the heat treatments, the magnetization directions of the respective ferromagnetic layers are thus stable as in the arrangement in FIG. 1. The MTJ structures 71 and 72 manufactured in the above method are operated as illustrated in FIGS. 2 and 3 and obtain the TMR ratios of 100% at the maximum.

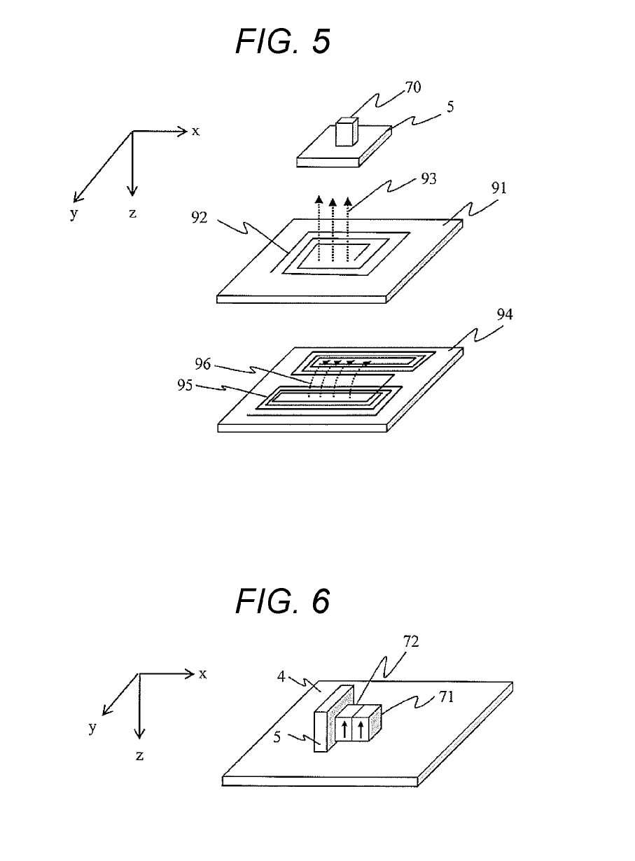

FIG. 5 is a schematic view illustrating a more practical mounting form of the magnetic sensor device according to the present embodiment. In this mounting form, a reset function is provided for a case in which a magnetization of a pinned layer of a magnetic sensor 70 is reversed for some reason. An insulating substrate 91 is provided with a coil 92, and current is supplied to the coil 92 to generate a magnetic field 93 in the film plane perpendicular direction (the −z direction). A substrate 94 is provided with a figure-of-eight coil 95 in which coils having different winding directions are paired, and current is supplied to the coil 95 to generate a magnetic field in the y direction. By arranging these coil substrates to overlap with a substrate 5 provided with the sensor device 70 and supplying current to the coils as needed to generate the magnetic fields in the y direction and the z direction, the magnetizations of the pinned layers can be returned to an initial state.

As described above, in Embodiment 1, by employing the structure of laminating the MTJ structure 71 and the MTJ structure 72, the magnetic fields in the two directions including the y direction and the z direction can be sensed by one device. Consequently, a space conventionally required for two magnetic sensors for the respective magnetic field directions can be reduced, mounting by connecting the plurality of magnetic sensors can further be simplified, and manufacturing cost can be reduced. As an application example of the magnetic sensor according to Embodiment 1, there is a case in which the magnetic sensor is applied to an electronic compass measuring geomagnetism. By laying down and arranging the device to have sensitivity in two horizontal axes (the x axis and the y axis), an orientation in a horizontal plane can be measured. FIG. 6 is a schematic view of the mounting. As illustrated in the figure, the device according to the present embodiment is laid down on a substrate 4 and is arranged so that the two MTJ structures 71 and 72 may be arrayed in the xy plane. The arrows in the figure indicate the directions of the axes of easy magnetization of the free layers in the respective MTJ structures. In this arrangement, the MTJ structure 71 has sensitivity in the x direction in the figure, and the MTJ structure 72 has sensitivity in the y direction. By measuring resistance values of the respective MTJ structures, magnitudes of the magnetic fields currently applied to the device in the x direction and the y direction are found. Based on the magnitudes, an angle of the magnetic field vector can be calculated. Accordingly, how much the current device is inclined to the geomagnetism is found, and a current orientation can be measured.

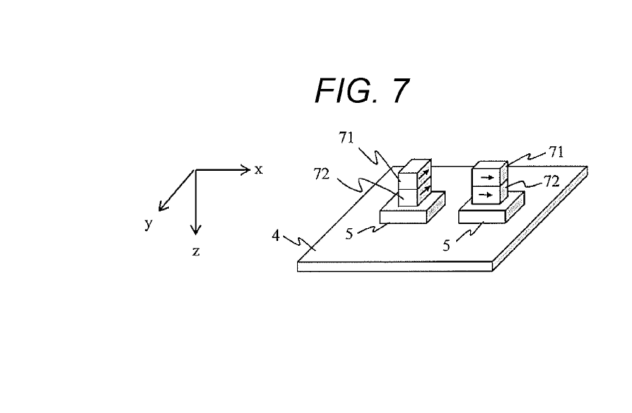

As a further developed application example, by using the two devices according to the present embodiment, a magnetic sensor in three axial directions including the two horizontal directions and a perpendicular direction can be achieved. FIG. 7 illustrates arrangement of the magnetic sensor devices for achieving the magnetic sensor in the three axial directions. As in FIG. 7, by arraying the two sensor devices to have a 90-degree difference in a plane, the lower-stage MTJ structures 72 of the two sensor devices measure the magnetic fields in the horizontal x and y directions, and the upper-stage MTJ structures 71 of the two sensor devices measure the magnetic field in the perpendicular z direction. This configuration is also more effective for space saving and easiness of mounting than a mounting form of arraying three conventional sensor devices each having sensitivity in one axis. The sensor device according to the present embodiment can be applied not only to the aforementioned electronic compass but also to a magnetic sensor system, installed at a tip end of a catheter to sense a position and posture information of the tip end as a medical application, and the like.

In the present embodiment, the film thickness of the CoFeB used as the pinned layer 22 is 0.5 nm or more at the minimum, 3 nm or less at the maximum, and more preferably from 1 nm to 2 nm. The reason for this is that the CoFeB does not function as a ferromagnet when the film thickness thereof is too short and that the strength of the perpendicular magnetic anisotropy decreases when the film thickness thereof is too long. Also, although the Co₂₀Fe₆₀B₂₀ is used as the free layers 21 and 23 and the pinned layers 22 and 24 in the present embodiment, another composition such as Co₄₀Fe₄₀B₂₀ may be used. Also, it is to be understood that a similar effect can be obtained by using another material having a bcc crystal structure such as CoFe and Fe instead of the CoFeB. Also, as a material having the perpendicular magnetic anisotropy for the pinned layer 22, an L1₀-type ordered alloy such as Co₇₅Pt₂₅, Co₅₀Pt₅₀, Fe₅₀Pt₅₀, and Fe₅₀Pd₅₀, an m-D0₁₉-type Co₇₅Pt₂₅ ordered alloy, a granular material, such as CoCrPt—SiO₂ and FePt—SiO₂, in which a granular magnetic body is dispersed in a mother phase of a non-magnetic body, a laminated film in which an alloy containing one or more out of Fe, Co, and Ni and a non-magnetic metal such as Ru, Pt, Rh, Pd, and Cr are alternately laminated, a laminated film in which Co and Ni are alternately laminated, or an amorphous alloy, such as TbFeCo and GdFeCo, containing a rare-earth metal such as Gd, Dy, and Tb and a transition metal may be used instead of the CoFeB. However, each of these perpendicular magnetic anisotropic materials (except the amorphous alloy) is significantly influenced by a crystal orientation and a surface planarity of an underlayer, and the perpendicular magnetic anisotropy may decrease. Thus, control of the underlayer is more important. Also, in a case of using each of these perpendicular magnetic anisotropic materials, it is generally more difficult than in a case of using the CoFeB to achieve crystal conformation suitable for a high TMR ratio to the barrier layer.

From such viewpoints, the CoFeB, which can switch between the in-plane magnetic anisotropy and the perpendicular magnetic anisotropy only by controlling the film thickness and can achieve the TMR ratio of 100% or higher with being less concerned about the influence of the underlayer on the crystal orientation, is most preferable as a ferromagnetic material in the present embodiment. Furthermore, by adjusting the film thickness of the CoFeB so that the axis of easy magnetization may be barely in the film plane perpendicular direction, the device in which the magnetization reacts to a weak perpendicular magnetic field can be manufactured. In other words, in the magnetic field dependence characteristic of the resistance change, inclination of the resistance change region can be significant, and the device having high sensitivity to the applied magnetic field can be obtained. In this respect as well, the CoFeB is a more suitable material for application to a sensor than the conventional perpendicular magnetization material (which inherently has strong perpendicular magnetic anisotropy and whose magnetization is not easily rotated in a small magnetic field).

### Embodiment 2

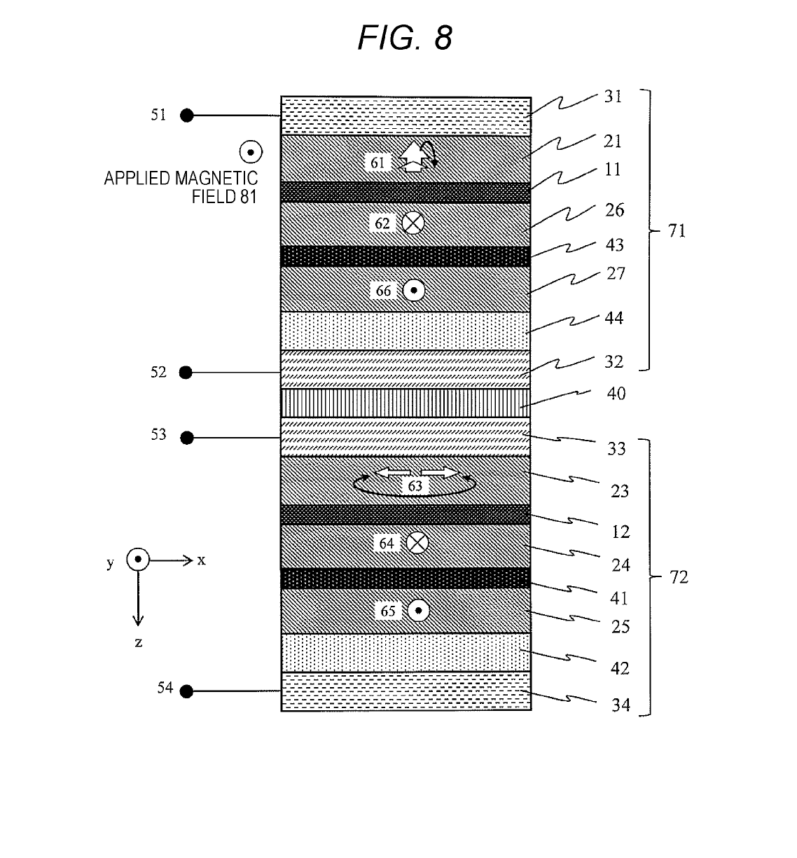

Embodiment 2 proposes a sensor that can measure both a small magnetic field and a relatively large magnetic field by using one device. FIG. 8 is a schematic cross-sectional view of a sensor device according to Embodiment 2. The device according to the present embodiment also has a structure of laminating two MTJ structures in a similar manner to Embodiment 1. A more specific structure (corresponding to FIG. 4) and a manufacturing method for mounting are similar to those in Embodiment 1 except that a partial thin film laminating configuration is different.

A thin film laminating configuration of the lower-stage MTJ structure 72 and a material and a film thickness of the spacer layer 40 are similar to those in Embodiment 1. On the other hand, a thin film laminating configuration of the upper-stage MTJ structure 71 is different from that in Embodiment 1. The upper-stage MTJ structure 71 according to Embodiment 2 includes a pinned layer having an in-plane axis of easy magnetization and a free layer having a perpendicular axis of easy magnetization. The pinned layer has a synthetic ferromagnetic structure including a first ferromagnetic layer 26, a non-magnetic layer 43, and a second ferromagnetic layer 27 in a similar manner to that in the lower-stage MTJ structure 72, and as an underlayer thereof, an antiferromagnetic layer 44 is inserted. Materials and film thicknesses of the respective layers forming the pinned layer having the synthetic ferromagnetic structure, the antiferromagnetic layer 44, and the barrier layer 11 are similar to those in the lower-stage MTJ structure 72.

On the other hand, the free layer 21 is constituted by thin Co₂₀Fe₆₀B₂₀ (1.7 nm), and an axis of easy magnetization is in the film plane perpendicular direction. As in FIG. 8, when an external magnetic field in the +y direction is applied, the magnetization 61 falls over from the film plane perpendicular direction to the +y direction in the film plane. Thus, since arrangement of the magnetization 61 with the magnetization 62 of the pinned layer first ferromagnetic layer 26 opposed to the magnetization 61 with the barrier layer 11 interposed therebetween is closer to antiparallel arrangement, the resistance of the MTJ structure 71 increases. Conversely, when the external magnetic field is applied in the −y direction, the magnetization 61 falls over in the −y direction, arrangement of the magnetization 61 with the magnetization 62 is closer to parallel arrangement, and the resistance of the MTJ structure 71 decreases.

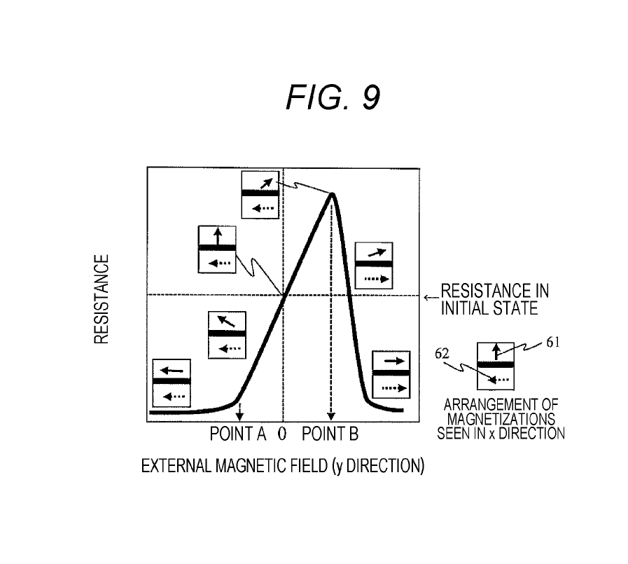

FIG. 9 is a schematic view illustrating this relationship between the external magnetic field and the resistance change. As illustrated in the figure, with use of a region (point A to point B) in which the resistance linearly changes in accordance with the external magnetic field, the magnetic field can be sensed. Meanwhile, when the magnetic field is higher than point B, the magnetization 62 on a side of the pinned layer, as well as the magnetization 61 of the free layer, is reversed, and the resistance thus decreases as illustrated in the figure.

The magnetic field dependence of the resistance of the lower-stage MTJ structure 72 is as illustrated in FIG. 2. In the case of the MTJ structure 72 according to the present embodiment, inclination of the resistance change in the linear region for use in sensing, that is, sensitivity, is the TMR ratio of 10% per 1 [Oe] (10% / Oe). Also, a measurable magnetic field range is ±5 Oe. On the other hand, sensitivity of the linear region (point A to point B) in the upper-stage MTJ structure 71 is 0.05%/Oe, which is lower than the above sensitivity, and a measurable magnetic field range (magnetic field range from point A to point B) is 1 kOe, which is conversely wider. The reason for this is that the magnetization 61 of the free layer 21 having the perpendicular magnetic anisotropy in the upper-stage MTJ structure 71 has more difficulty in being rotated against the external magnetic field than the magnetization 63 of the free layer 23 having the in-plane magnetic anisotropy in the lower-stage MTJ structure 72.

As described above, in the sensor device according to the present embodiment including the two types of MTJ structures, the magnetic fields in the two ranges including the small magnetic field and the large magnetic field can be sensed by one device. For example, this device can be applied to a current sensor arranged around a cable for motor driving in an electric car or a hybrid car to sense a circumference magnetic field generated when current flows. In such an application, a plurality of sensors having different sensitivity ranges are used conventionally to cover various current ranges. In comparison, by using the sensor device according to the present embodiment, the number of devices to be mounted, an arranging space, and cost can be reduced.

In the present embodiment, the film thickness of the CoFeB used as the free layer 21 is 0.5 nm or more at the minimum, 3 nm or less at the maximum, and more preferably from 1 nm to 2 nm. The reason for this is that the CoFeB does not function as a ferromagnet when the film thickness thereof is too short and that the strength of the perpendicular magnetic anisotropy decreases, and the in-plane magnetic anisotropy is dominant when the film thickness thereof is too long. Also, although the CoFeB is used as the free layers 21 and 23 and the pinned layers 26 and 24 in the present embodiment, it is to be understood that a similar effect can be obtained by using another material having a bcc crystal structure such as CoFe and Fe.

### Embodiment 3

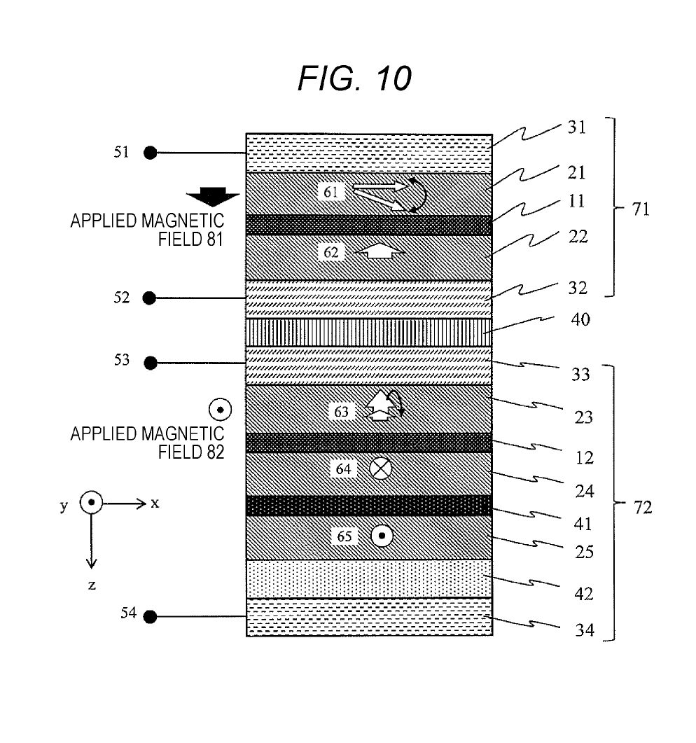

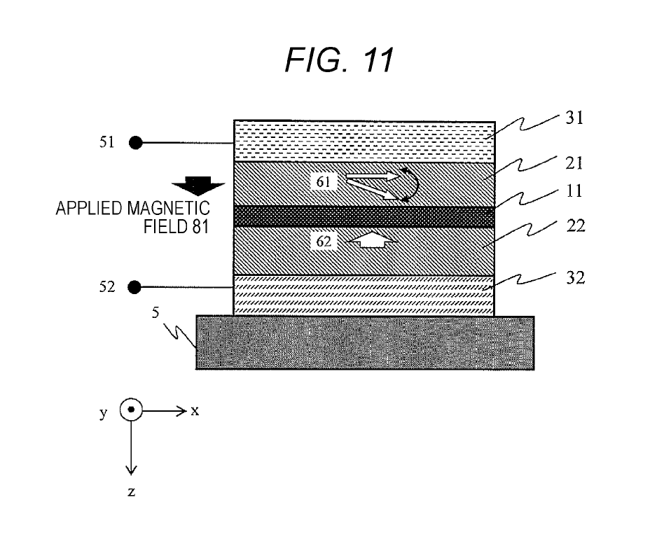

Embodiment 3 proposes a magnetic sensor having sensitivity in the y direction and the z direction as in Embodiment 1 and partially having a different configuration from that in Embodiment 1. FIG. 10 is a schematic cross-sectional view of a magnetic sensor device according to Embodiment 3.

In the magnetic sensor device according to the present embodiment, the upper-stage MTJ structure 71 has an equal configuration to that in Embodiment 1, and the lower-stage MTJ structure 72 has an equal configuration to the upper-stage MTJ structure in Embodiment 2. Materials and film thicknesses of the respective layers of these MTJ structures 71 and 72 in Embodiment 3 are similar to those of the MTJ structure 71 in Embodiment 1 and the MTJ structure 72 in Embodiment 2. In Embodiment 3, the upper-stage MTJ structure 71 has sensitivity to a magnetic field in the z direction while the lower-stage MTJ structure 72 has sensitivity to a magnetic field in the y direction. Due to this configuration, the magnetic fields can be sensed in two directions of y and z.

A manufacturing method is similar to that in Embodiment 1. As supplemental description, in the first heat treatment after the manufacture of the device, a 300° C. treatment is performed in a state in which a magnetic field is applied in the x direction to set the axis of easy magnetization of the free layer 21 in the x direction. Thereafter, the second heat treatment is performed at 200° C. by applying a magnetic field in the y direction to fix the axes of easy magnetization of the pinned layers 24 and 25 in the y direction. Since the pinned layer 22 and the free layer 23 have the perpendicular axes of easy magnetization, the directions of the magnetizations 62 and 63 are the film plane perpendicular directions in a stable manner regardless of the magnetic field applying direction during the heat treatments.

### Embodiment 4

Embodiment 4 proposes a high-sensitivity magnetic sensor for a perpendicular magnetic field that can be manufactured easily.

Conventionally, in a magnetic sensor using MTJ, the in-plane magnetic anisotropy is used in many cases. That is, the magnetic sensor employs a system of using as a signal a resistance change obtained by rotation of a magnetization in a free layer in a film plane against a magnetization direction of a pinned layer. Such an in-plane type of magnetic sensor is suitable for sensing a magnetic field in the horizontal direction due to a shape of the device formed on a flat substrate. On the other hand, to sense a magnetic field in the film plane perpendicular direction, the substrate on which the device is formed needs to be arranged to erect. Thus, mounting is complicated, and such arrangement is not suitable for space saving. Under such circumstances, to sense the magnetic field in the film plane perpendicular direction, a perpendicular type of sensor using combination of a pinned layer having the in-plane axis of easy magnetization and a free layer having the perpendicular axis of easy magnetization is proposed. However, a conventional ferromagnetic material having the perpendicular magnetic anisotropy is an L1₀-type ordered alloy represented by Co₅₀Pt₅₀ and a multilayer film with an artificial lattice represented by Co/Pt, and each of these has difficulty in achieving a high TMR ratio of 100% or higher from a viewpoint of crystal conformation to an MgO barrier. This causes a problem in which the conventional perpendicular type of magnetic sensor has lower sensitivity than that of the in-plane type of sensor.

As for the CoFeB, when the CoFeB is arranged to contact an oxide such as MgO, the direction of the magnetic anisotropy thereof can be changed from the in-plane direction to the film plane perpendicular direction only by controlling the film thickness. This results from the perpendicular magnetic anisotropy generated at an interface between the CoFeB and the oxide. Also, to achieve the high TMR ratio, combination of the CoFeB and the MgO barrier is excellent.

When this combination of the materials is employed in a magnetic sensor, a perpendicular type of magnetic sensor having higher sensitivity than a conventional one can be obtained easily. FIG. 11 is a schematic cross-sectional view of a magnetic sensor device according to Embodiment 4. The sensor device is configured by a laminated thin film on the Si substrate 5 having a thermally-oxidized film as illustrated in FIG. 11. The lower electrode 32 is constituted by a laminated film in which Ta (film thickness: 5 nm), Ru (film thickness: 10 nm), and Ta (film thickness: 5 nm) are laminated in this order from the bottom. On the lower electrode 32, the pinned layer 22, the barrier layer 11, and the free layer 21 are laminated in this order. Co₂₀Fe₆₀B₂₀ (1 nm) is used as the pinned layer 22, MgO (1.5 nm) is used as the barrier layer 11, and Co₂₀Fe₆₀B₂₀ (2.5 nm) is used as the free layer 21. On the free layer 21, a laminated film of Ta (5 nm) and Ru (5 nm) is formed as the upper electrode 31. To the upper electrode 31 and the lower electrode 32, the electrode terminals 51 and 52 are respectively connected to measure resistance. The magnetization 62 of the pinned layer 22 faces in the film plane perpendicular direction. The reason for this is that setting a film thickness of the Co₂₀Fe₆₀B₂₀ as short as approximately 1 nm increases an influence of interface magnetic anisotropy with the MgO interface and causes the axis of easy magnetization of the pinned layer 22 to change from the direction in the film plane to the film plane perpendicular direction. On the other hand, the magnetization 61 of the free layer 21 faces in the x direction in the film plane. The reason for this is that the free layer 21 is the 2-nm Co₂₀Fe₆₀B₂₀, which is relatively thick, and that the axis of easy magnetization of the free layer 21 faces in the in-plane direction. Since the perpendicular magnetic anisotropy of the pinned layer 22 is generally stronger than the in-plane magnetic anisotropy, the magnetization 62 can be fixed in a stable manner with no antiferromagnetic layer. In a case in which the magnetization of the pinned layer 22 is desired to be fixed more strongly, an antiferromagnetic layer may be inserted between the lower electrode 32 and the pinned layer 22 as needed. Also, the film thickness of the Co₂₀Fe₆₀B₂₀ as the pinned layer 22 does not have to be 1 nm, but the film thickness is preferably in a range of from 0.5 nm or higher to 2 nm or lower to generate the perpendicular magnetic anisotropy.

The above laminated film is manufactured by means of the RF sputtering using Ar and is then processed in a pillar shape of 30×30 μm as seen from an upper portion by means of the photolithography and the ion beam etching. Subsequently, the electrode terminals 51 and 52 are respectively connected to the upper electrode 31 and the lower electrode 32. Lastly, a heat treatment is performed at 300° C. by applying a magnetic field in the x direction to fix the axis of easy magnetization of the free layer 21 in the x direction.

When a magnetic field is applied to the manufactured magnetic sensor in the film plane perpendicular direction (z direction), the magnetization 61 of the free layer 21 is inclined in the z direction. Since arrangement of the magnetization 61 with the magnetization 62 of the pinned layer 22 is closer to antiparallel arrangement, the resistance of the device increases. Conversely, when a magnetic field is applied in the −z direction, arrangement of the magnetization 61 with the magnetization 62 is closer to parallel arrangement, and the resistance of the device decreases. Based on such an operation principle, an excellent linear characteristic with no hysteresis as illustrated in FIG. 3 can be obtained. In the present embodiment, by using the CoFeB for the ferromagnetic layer having the perpendicular magnetic anisotropy, the resistance change ratio (the TMR ratio) of 100% at the maximum is obtained. Also, the resistance change ratio per 1 Oe is approximately 1%, and sensitivity enabling sensing of, e.g., the geomagnetism, is obtained.

With the above configuration, the magnetic sensor according to the present embodiment has higher sensitivity than the conventional perpendicular type of magnetic sensor and can sense the perpendicular magnetic field without arranging the sensor substrate to erect as in the case of the in-plane type of magnetic sensor. Due to these effects, the magnetic sensor according to the present embodiment can be applied to a small-sized magnetic compass, an in-vehicle small-sized magnetic sensor, a magnetic sensor at a tip end of a catheter as a medical application, and the like.

### Embodiment 5

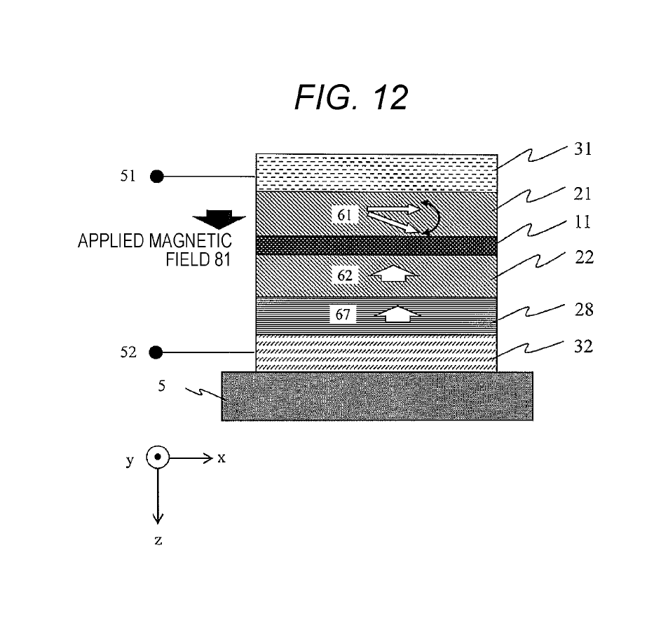

Embodiment 5 proposes a sensor device structure in which a magnetization of a pinned layer is more stable than that in Embodiment 4 based on the structure in Embodiment 4. FIG. 12 is a schematic cross-sectional view of a magnetic sensor device according to Embodiment 5.

In Embodiment 5, a basic structure is equal to that in Embodiment 4, and a pinned layer second ferromagnetic layer 28 is inserted below the pinned layer 22. As a material for the ferromagnetic layer 28, a multilayer film in which Co (0.4 nm) and Pt (0.6 nm) are alternately laminated six times is used. Since a magnetization 67 of the ferromagnetic layer 28 is ferromagnetically coupled with the magnetization 62 of the pinned layer 22, the magnetization 62 is fixed more strongly than in Embodiment 1. For this reason, even in a case in which a large magnetic field is applied from an external side, an effect of suppressing magnetization reversal of the pinned layer is obtained.

Although the Co/Pt laminated film is used as a material for the pinned layer second ferromagnetic layer 28 in the present embodiment, another material having the perpendicular magnetic anisotropy may be used. For example, an L1₀-type ordered alloy such as Co₇₅Pt₂₅, Co₅₀Pt₅₀, Fe₅₀Pt₅₀, and Fe₅₀Pd₅₀, an m-D0₁₉-type Co₇₅Pt₂₅ ordered alloy, a granular material, such as CoCrPt—SiO₂ and FePt—SiO₂, in which a granular magnetic body is dispersed in a mother phase of a non-magnetic body, a laminated film in which an alloy containing one or more out of Fe, Co, and Ni and a non-magnetic metal such as Ru, Pt, Rh, Pd, and Cr are alternately laminated, a laminated film in which Co and Ni are alternately laminated, or an amorphous alloy, such as TbFeCo and GdFeCo, containing a rare-earth metal such as Gd, Dy, and Tb and a transition metal may be used.

Aspects of the magnetic sensor devices aforementioned in Embodiments 4 and 5 are described below.

(1) A magnetic sensor device having a tunneling magnetoresistive effect device structure including a free layer constituted by a ferromagnetic thin film whose magnetization direction changes depending on an external magnetic field, a pinned layer constituted by a ferromagnetic film whose magnetization direction is fixed in one direction, and an oxide tunneling barrier layer arranged between the free layer and the pinned layer, wherein an upper electrode layer and a lower electrode layer are provided at an upper portion and a lower portion of the magnetic sensor device, wherein, to the upper electrode layer and the lower electrode layer are connected electrode terminals to measure resistance of the magnetic sensor device, and wherein an axis of easy magnetization of the free layer is in a direction in a film plane while an axis of easy magnetization of the pinned layer is in a direction perpendicular to a film plane.

(2) The magnetic sensor device according to the above (1), wherein the pinned layer includes a first ferromagnetic layer and a second ferromagnetic layer, and wherein magnetizations of the first ferromagnetic layer and the second ferromagnetic layer are ferromagnetically coupled.

(3) The magnetic sensor device according to the above (1), wherein at least one out of the ferromagnetic thin films constituting the free layer and the pinned layer is Fe, CoFe, or CoFeB.

(4) The magnetic sensor device according to the above (1), wherein, among the free layer and the pinned layer, a magnetization direction of the ferromagnetic thin film having a perpendicular axis of easy magnetization faces in a direction perpendicular to a film plane by controlling a film thickness, and the film thickness is in a range of from 0.5 nm to 3 nm.

(5) The magnetic sensor device according to the above (1) to (4), wherein the tunneling barrier layer is MgO.

The present invention is not limited to the foregoing embodiments and includes various modification examples. For example, the foregoing embodiments have been described in detail to facilitate understanding of the present invention, and the present invention is not limited to one including all of the components described herein. Also, some components of one embodiment can be substituted with components of another embodiment, and components of another embodiment can be added to components of one embodiment. Further, some components of each embodiment can be added, deleted, and substituted with other components.

### REFERENCE SIGNS LIST

4, 5 substrate
11, 12 barrier layer
21 free layer
22 pinned layer
23 free layer
24 pinned layer first ferromagnetic layer
25 pinned layer second ferromagnetic layer
26 pinned layer first ferromagnetic layer
27 pinned layer second ferromagnetic layer
28 pinned layer second ferromagnetic layer
31 upper electrode
32 lower electrode
33 upper electrode
34 lower electrode
40 spacer layer
41 non-magnetic layer
42 antiferromagnetic layer
43 non-magnetic layer
44 antiferromagnetic layer
71 upper-stage MTJ structure
72 lower-stage MTJ structure
81, 82 applied magnetic field
91, 94 substrate
92, 95 coil
93, 96 magnetic field

1. A magnetic sensor device comprising:
a first tunneling magnetoresistive effect device;
a second tunneling magnetoresistive effect device laminated on the first tunneling magnetoresistive effect device;
a first upper electrode layer and a first lower electrode layer arranged at an upper portion and a lower portion of the first tunneling magnetoresistive effect device;
a second upper electrode layer and a second lower electrode layer arranged at an upper portion and a lower portion of the second tunneling magnetoresistive effect device;
electrode terminals connected to the first upper electrode layer and the first lower electrode layer to measure resistance of the first tunneling magnetoresistive effect device; and
electrode terminals connected to the second upper electrode layer and the second lower electrode layer to measure resistance of the second tunneling magnetoresistive effect device,
wherein each of the first tunneling magnetoresistive effect device and the second tunneling magnetoresistive effect device includes a free layer constituted by a ferromagnetic thin film whose magnetization direction changes depending on an external magnetic field, a pinned layer constituted by a ferromagnetic thin film whose magnetization direction is fixed in one direction, and an oxide tunneling barrier layer arranged between the free layer and the pinned layer, and
in at least one out of the first tunneling magnetoresistive effect device and the second tunneling magnetoresistive effect device, axes of easy magnetization of the free layer and the pinned layer included in the tunneling magnetoresistive effect device are perpendicular in a direction in a film plane and in a direction perpendicular to a film plane.

2. The magnetic sensor device according to claim 1, wherein an axis of easy magnetization of the pinned layer of the first tunneling magnetoresistive effect device or the pinned layer of the second tunneling magnetoresistive effect device faces in a direction perpendicular to a film plane.

3. The magnetic sensor device according to claim 1, wherein an axis of easy magnetization of the free layer of the first tunneling magnetoresistive effect device or the free layer of the second tunneling magnetoresistive effect device faces in a direction perpendicular to a film plane.

4. The magnetic sensor device according to claim 1, wherein the pinned layer of the first tunneling magnetoresistive effect device or the pinned layer of the second tunneling magnetoresistive effect device has a structure in which a non-magnetic metal layer is interposed between a first ferromagnetic layer and a second ferromagnetic layer and has a synthetic ferromagnetic structure in which magnetization directions of the first ferromagnetic layer and the second ferromagnetic layer are coupled to be antiparallel to each other.

5. The magnetic sensor device according to claim 1, wherein at least one out of the ferromagnetic thin films constituting the free layers and the pinned layers is Fe, CoFe, or CoFeB.

6. The magnetic sensor device according to claim 5, wherein, among the free layers and the pinned layers, a film thickness of the ferromagnetic thin film whose axis of easy magnetization faces in a direction perpendicular to a film plane is in a range of from 0.5 nm to 3 nm.

7. The magnetic sensor device according to claim 5, wherein, among the free layers and the pinned layers, a material for the ferromagnetic thin film whose axis of easy magnetization faces in a direction perpendicular to a film plane is a laminated film in which an alloy containing any one or more out of Fe, Co, and Ni and any one out of Ru, Pt, Rh, Pd, and Cr are alternately laminated.

8. The magnetic sensor device according to claim 5, wherein, among the free layers and the pinned layers, a material for the ferromagnetic thin film whose axis of easy magnetization faces in a direction perpendicular to a film plane is a granular material in which a granular magnetic phase is surrounded by a non-magnetic phase.

9. The magnetic sensor device according to claim 5, wherein, among the free layers and the pinned layers, a material for the ferromagnetic thin film whose axis of easy magnetization faces in a direction perpendicular to a film plane is an amorphous alloy containing a rare-earth metal and a transition metal.

10. The magnetic sensor device according to claim 5, wherein, among the free layers and the pinned layers, a material for the ferromagnetic thin film whose axis of easy magnetization faces in a direction perpendicular to a film plane is an m-D0₁₉-type CoPt ordered alloy, an L1₁-type CoPt ordered alloy, or an L1₀-type ordered alloy consisting primarily of Co—Pt, Co—Pd, Fe—Pt, or Fe—Pd.

11. The magnetic sensor device according to claim 1, wherein the tunneling barrier layer is MgO.
